(19) United States
(12) Patent Application Publication
(10) Pub. No.: US 2004/0097049 A1
(43) Pub. Date: May 20, 2004

(54) Semiconductor device and method for manufacturing a semiconductor device

(75) Inventor: Hirofumi Kawai, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 10/638,401

(22) Filed: Aug. 12, 2003

(30) Foreign Application Priority Data
Aug. 15, 2002 (JP) 2002-236930

(51) Int. Cl. H01L 21/331; H01L 21/8222

(52) U.S. Cl. 438/314

(57) ABSTRACT

A semiconductor device comprises a collector layer comprising a first kind of semiconductor material; a base layer including a first base portion and a second base portion, said first base portion coming in contact with the first collector layer and comprising the first kind of semiconductor material, said second base portion coming in contact with the first base portion and comprising a second kind of semiconductor material; and an emitter layer coming in contact with the base layer and comprising the first kind of semiconductor material, said emitter layer forming a heterojunction with the base layer.

### CROSS-REFERENCE TO RELATED APPLICATION

This application is based upon and claims the benefit of priority from the prior Japanese Patent Application No. 2002-236930, filed on Aug. 15, 2002, the entire contents of which are incorporated herein by reference.

### BACKGROUND OF THE INVENTION

1. Field of the Invention

The present invention relates to a semiconductor device and a method for manufacturing a semiconductor device.

2. Related Background Art

As an RFIC (Radio Frequency Integrated Circuit) used in such communication apparatus as a cellar or mobile telephone or the like, BICMOS provided with bipolar transistors and MOS transistors in a mixed manner are frequently used. In particular, in order to make it possible to use the bipolar transistor in a high frequency region such as RF, a cut-off frequency f_{T} of a BICMOS must be made high.

In general, in order to make the cut-off frequency f_{T} of a bipolar transistor high, a base layer of the transistor is ordinarily made narrow. That is, a distance between an emitter and a collector is shortened. Since a punch through between the emitter and the collector tends to occur easily when the base layer becomes narrow, an impurity density in the base layer must be high. However, when the impurity density in the base layer is made high, a current amplification rate h_{FE} becomes lower due to lowering of an injection efficiency from the emitter.

Conventionally, in order to prevent increase of a base resistance or lowering of a breakdown voltage while raising cut-off frequency f_{T}, there is a heterojunction bipolar transistor (HBT) using heterojunction between an emitter and a base. For example, a BICMOS with a heterojunction comprising mixed crystal of silicone and silicon germanium (Si—Ge) is frequently used.

FIG. 10 is an illustrative sectional view of a conventional BICMOS using Si—Ge. In FIG. 10, a boundary is shown with one dotted chain line, and an MIS transistor region is shown on the right side thereof and a bipolar transistor region is shown on the left side thereof. A constitution of the bipolar transistor region will be explained.

A buried layer 12 is formed in a silicon substrate 10, and a silicon single crystal layer 14 is formed on the buried layer 12. The buried layer 12 is electrically connected to a lead layer 16 and a contact layer 18, and it is electrically connected to a contact electrode C via the lead layer 16 and the contact layer 18. Each of the buried layer 12, the silicon single crystal layer 14, the lead layer 16 and the contact layer 18 is made of N-type or N⁺-type semiconductor, and the silicon single crystal layer 14 serves as a collector layer.

A Si—SiGe—Si stacked film 20 obtained by epitaxially growing a silicon single crystal, a mixed crystal of silicon germanium and a silicon single crystal are continuously provided on the silicon single crystal layer 14. One portion of this Si—SiGe—Si stacked film 20 is made of P-type semiconductor and it serves as a base layer. The base layer is electrically connected to a base electrode B via a polycrystalline silicon 22.

A polycrystalline silicon 24 is formed on the Si—SiGe—Si stacked film 20. The polycrystalline silicon 24 is dosed with N-type impurities, and the N-type impurities are diffused on an upper portion of the Si—SiGe—Si stacked film 20. Thereby, an emitter layer is formed on the upper portion of the Si—SiGe—Si stacked film 20 and a heterojunction is formed between the base and the emitter. The emitter layer is electrically connected to an emitter electrode E via the polycrystalline silicon 24. Thus, an NPN bipolar transistor, which comprises the base electrode B, the emitter electrode E and the collector electrode C and which has the heterojunction between the base and the emitter, is constituted.

A P⁺-type source layer 32 is provided in the MIS transistor region on one side of an N-type channel portion 30. A P⁺-type drain layer 34 is provided in the MIS transistor region on another side of the N-type channel portion 30. Further, a gate portion 38 is formed on the channel portion 30 via a gate insulating film 36. A source electrode S, a drain electrode D and a gate electrode G are electrically connected to the source layer 32, the drain layer 34 and the gate portion 38, respectively. Thus, a PMOS transistor comprising the source electrode S and the drain electrode D and the gate electrode G is constituted. Furthermore, an isolation portion 40 is provided for isolating these semiconductor devices.

FIG. 11 is a graph showing an impurity concentration profile of a device section and a germanium percentage content in the silicon germanium taken along line A-A in FIG. 10. A horizontal axis of the graph shows a depth directed toward the silicon substrate 10 assuming that a surface of the Si—SiGe—Si stacked film 20 is zero. A left side vertical axis on this graph shows an impurity concentration and a right side vertical axis shows a germanium percentage content in the silicon germanium.

In the Si—SiGe—Si stacked film 20, arsenic (As) is diffused in the vicinity of its surface, so that an emitter is formed. A base containing boron (B) is formed below an emitter region. Further, a collector containing phosphorus (P) is formed below the base.

The mixed crystal of silicon germanium extends over the base and the collector. That is, a junction between the collector and the base comprises a mixed crystal of silicon germanium. When inverse bias is applied between the collector and the base, a depletion layer largely extends to the collector side having a low impurity concentration as shown with D1 in FIG. 11.

At this time, since an SiGe layer is included in the region of the depletion layer D1, a collector-base junction breakdown voltage (BVcbo) of the bipolar transistor is lowered. This is because an energy gap of silicon is about 1.1 eV while energy gap of germanium is low at about 0.67 eV, and a breakdown field of silicon is about 30 V/μm while a breakdown field is low at about 8V/μm.

The lowering of the collector-base junction breakdown voltage (BVcbo) causes lowering of an emitter-collector breakdown voltage (BVceo) correlated with the collector-base breakdown voltage. As a result, there occurs such a problem that an operation voltage range of the bipolar transistor becomes narrow.

### SUMMARY OF THE INVENTION

In view of the above, the object of an embodiment according to the present invention is to provide a semiconductor device which has a bipolar transistor including a heterojunction between a base and an emitter, and which has an emitter-collector breakdown voltage higher than that of a conventional bipolar transistor.

In order to achieve the above-described advantage, a semiconductor device comprises a collector layer comprising a first kind of semiconductor material; a base layer including a first base portion and a second base portion, said first base portion coming in contact with the first collector layer and comprising the first kind of semiconductor material, said second base portion coming in contact with the first base portion and comprising a second kind of semiconductor material; and an emitter layer coming in contact with the base layer and comprising the first kind of semiconductor material, said emitter layer forming a heterojunction with the base layer.

A method for manufacturing a semiconductor device comprises forming a first layer on a semiconductor substrate, said first layer comprising a first kind of semiconductor material which includes impurities for a collector; forming a second layer, a third layer and a fourth layer on the first layer, said second layer comprising the first kind of semiconductor material which is not doped with impurities, said third layer comprising a second kind of semiconductor material which is not doped with impurities, and said fourth layer comprising the second kind of semiconductor material which includes impurities for a base; forming a fifth layer on the fourth layer, said fifth layer comprising the first kind of semiconductor material which includes impurities for an emitter; and diffusing the impurities for a base to the second layer.

### BRIEF DESCRIPTION OF THE DRAWINGS

FIG. 1 is an illustrative sectional view of a BICMOS 200 according to an embodiment of the present invention;

FIG. 2 is a graph showing an impurity concentration profile and a germanium percentage content of a Si—SiGe—Si stacked film 220 taken along line 2-2 in FIG. 1;

FIG. 3A is a device sectional view showing a method for manufacturing the BICMOS 200;

FIG. 3B is a device sectional view showing a method for manufacturing the BICMOS 200, which is continuous to the method shown in FIG. 3A;

FIG. 3C is a device sectional view showing a method for manufacturing the BICMOS 200, which is continuous to the method shown in FIG. 3B;

FIG. 3D is a device sectional view showing a method for manufacturing the BICMOS 200, which is continuous to the method shown in FIG. 3C;

FIG. 4A is a device sectional view showing a method for manufacturing the BICMOS 200, which is continuous to the method shown in FIG. 3D;

FIG. 4B is a device sectional view showing a method for manufacturing the BICMOS 200, which is continuous to the method shown in FIG. 4A;

FIG. 4C is a device sectional view showing a method for manufacturing the BICMOS 200, which is continuous to the method shown in FIG. 4B;

FIG. 4D is a device sectional view showing a method for manufacturing the BICMOS 200, which is continuous to the method shown in FIG. 4C;

FIG. 5A is a device sectional view showing a method for manufacturing the BICMOS 200, which is continuous to the method shown in FIG. 4D;

FIG. 5B is a device sectional view showing a method for manufacturing the BICMOS 200, which is continuous to the method shown in FIG. 5A;

FIG. 5C is a device sectional view showing a method for manufacturing the BICMOS 200, which is continuous to the method shown in FIG. 5B;

FIG. 5D is a device sectional view showing a method for manufacturing the BICMOS 200, which is continuous to the method shown in FIG. 5C;

FIG. 6A is a device sectional view showing a method for manufacturing the BICMOS 200, which is continuous to the method shown in FIG. 5D;

FIG. 6B is a device sectional view showing a method for manufacturing the BICMOS 200, which is continuous to the method shown in FIG. 6A;

FIG. 6C is a device sectional view showing a method for manufacturing the BICMOS 200, which is continuous to the method shown in FIG. 6B;

FIG. 6D is a device sectional view showing a method for manufacturing the BICMOS 200, which is continuous to the method shown in FIG. 6C;

FIG. 7A is a device sectional view showing a method for manufacturing the BICMOS 200, which is continuous to the method shown in FIG. 6D;

FIG. 7B is a device sectional view showing a method for manufacturing the BICMOS 200, which is continuous to the method shown in FIG. 7A;

FIG. 7C is a device sectional view showing a method for manufacturing the BICMOS 200, which is continuous to the method shown in FIG. 7B;

FIG. 7D is a device sectional view showing a method for manufacturing the BICMOS 200, which is continuous to the method shown in FIG. 7C;

FIG. 8A is a device sectional view showing a method for manufacturing the BICMOS 200, which is continuous to the method shown in FIG. 7D;

FIG. 8B is a device sectional view showing a method for manufacturing the BICMOS 200, which is continuous to the method shown in FIG. 8A;

FIG. 8C is a device sectional view showing a method for manufacturing the BICMOS 200, which is continuous to the method shown in FIG. 8B;

FIG. 8D is a device sectional view showing a method for manufacturing the BICMOS 200, which is continuous to the method shown in FIG. 8C;

FIG. 9A is a device sectional view showing a method for manufacturing the BICMOS 200, which is continuous to the method shown in FIG. 8D;

FIG. 9B is a device sectional view showing a method for manufacturing the BICMOS 200, which is continuous to the method shown in FIG. 9A;

FIG. 9C is a device sectional view showing a method for manufacturing the BICMOS 200, which is continuous to the method shown in FIG. 9B;

FIG. 10 is an illustrative sectional view of a conventional BICMOS using Si—Ge; and

FIG. 11 is a graph showing an impurity concentration profile and a silicon germanium percentage content of a device section taken along line A-A in FIG. 10.

### DETAILED DESCRIPTION OF THE INVENTION

An embodiment according to the present invention will be explained below with reference to the drawings. Incidentally, the embodiment does not limit the present invention. Further, in the following embodiment, even when N-type semiconductor is used instead of the P-type semiconductor and P-type conductor is used instead of the N-type semiconductor, an effect or an advantage of the present invention or the present embodiment can be obtained.

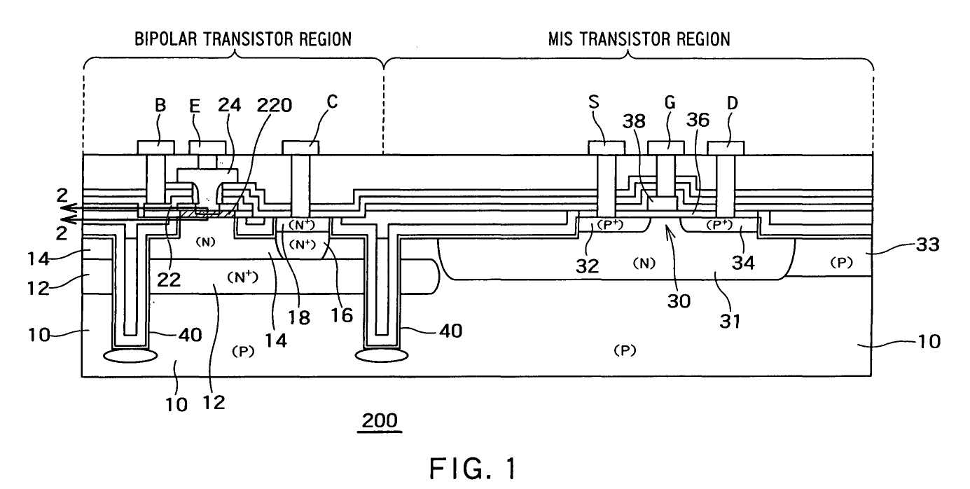

FIG. 1 is an illustrative sectional view of a BICMOS 200 according to an embodiment of the present invention. In FIG. 1, a MIS transistor region is shown on the right side of a boundary depicted with one dotted chain line and a heterojunction bipolar transistor region is shown on the left side thereof.

First, a bipolar transistor formed on the bipolar transistor region will be explained. The bipolar transistor is provided with a P-type silicon substrate 10, an N⁺-buried layer 12 is formed in the silicon substrate 10, and an N-type silicon single crystal layer 14 is formed on the buried layer 12. Arsenic (As) is contained in the buried layer 12 as an N-type impurity, and phosphorus (P) is contained in the silicon single crystal layer 14 as an N-type impurity.

The buried layer 12 is connected to a N⁺-lead layer 16, the lead layer 16 is connected to a N⁺-type contact layer 18, and the contact layer 18 is connected to a collector electrode C. Phosphorus (P) is contained in the lead layer 16, and arsenic (As) is contained in the contact layer 18.

Thereby, the silicon single crystal layer 14 is electrically connected to the collector layer C via the buried layer 12, the lead layer 16 and the contact layer 18, so that the silicon single crystal layer 14 serves as a collector layer of the bipolar transistor. Since all of the buried layer 12, the lead layer 16 and the contact layer 18 are of N⁺-type conductivity, the silicon single crystal layer 14 and the collector electrode C are connected through a low resistance.

A Si—SiGe—Si stacked layer 220, which is formed by epitaxially growing silicon single crystal, mixed crystal of silicon germanium and silicon single crystal continuously, is provided on the silicon single crystal layer 14.

A silicon germanium (SiGe) portion of the Si—SiGe—Si stacked layer 220 contains boron (B) to be formed as P-type semiconductor. The P-type silicon germanium serves as one portion of a base layer of the bipolar transistor. The base layer is electrically connected to a base electrode B via polycrystalline silicon 22.

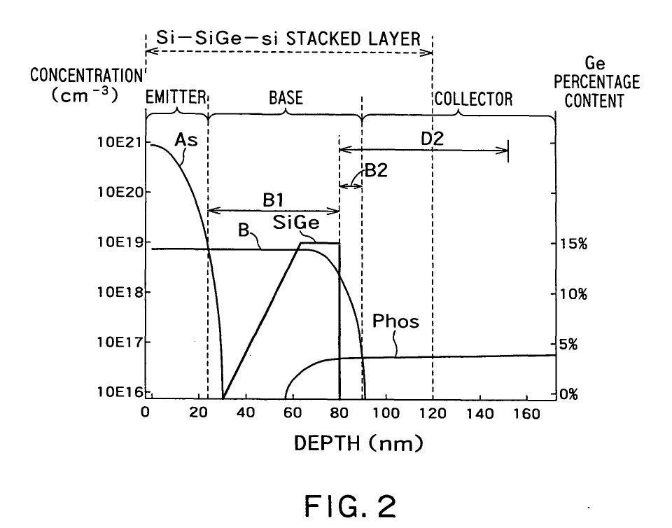

A polycrystalline silicon 24 containing arsenic (As) as an N-type impurity is positioned on the Si—SiGe—Si stacked layer 220 adjacent thereto. Further, the silicon single crystal layer 14 containing phosphorus (P) is positioned below the Si—SiGe—Si stacked layer 220 adjacent thereto. By conducting a heat treatment in this configuration, arsenic (As) and phosphorus (P) are respectively diffused in an upper portion and a lower portion of the Si—SiGe—Si stacked layer 220. As a result, a N-type emitter layer is formed in the upper portion of the Si—SiGe—Si stacked layer 220, an N-type collector layer is formed in the lower portion thereof, and a P-type base layer is formed in an intermediate portion between the upper portion and the lower portion. Thereby, a heterojunction comprising silicon and silicon germanium is formed between the base and the emitter. The constitution of the Si—SiGe—Si stacked layer 220 therein will be explained in detail in FIG. 2.

The emitter layer is electrically connected to an emitter electrode E via the polycrystalline silicon 24. Thus, an NPN bipolar transistor provided with the base electrode B, the emitter electrode E and the collector electrode C is constituted. Of course, the number of NPN bipolar transistors to be formed is generally plural and it is not limited. Further, by changing conductive types of respective constitution elements of the NPN bipolar transistor, a PNP bipolar transistor may be constituted. Furthermore, NPN bipolar transistors and PNP transistors may be mounted in a mixed manner.

FIG. 2 is a graph showing an impurity concentration profile and a germanium percentage content of a Si—SiGe—Si stacked film 220 taken along line 2-2 in FIG. 1.

A horizontal axis in this graph shows a depth directed toward the silicon substrate 10 assuming that a surface of the Si—SiGe—Si stacked film 220 is zero. A left side vertical axis on this graph shows an impurity concentration and a right side vertical axis shows a germanium percentage content.

In the Si—SiGe—Si stacked film 220, arsenic (As) is diffused in the vicinity of its surface from the polycrystalline silicon 24, so that an emitter layer is formed. A base layer containing boron (B) is formed under an emitter region. Further, phosphorus (P) is diffused below the base layer from the silicon single crystal layer 14 so that a collector layer is formed.

Mixed crystal of silicon germanium is made thinner than that in the conventional one and exists only in one portion. For example, the thickness of silicon germanium containing germanium of about 15% is conventionally about 60 nm while the thickness thereof according to the present embodiment is about 20 nm. Thereby, no silicon germanium exists in the collector layer or a junction portion between the collector and the base, but silicon single crystal exists therein.

A junction between the base and the collector is a portion of boron, (B) which is the impurity in the base layer, and phosphorus (P), which is the impurity in the collector, adjacent to each other. When an inverse bias is applied to the junction between the base and the collector, a depletion layer extends as shown with D2 in FIG. 2. That is, the depletion layer extends largely to the side of the collector with a low impurity concentration (an arsenic concentration), and only extends slightly to the side of the base with a high impurity concentration (a boron concentration). It is assumed that a region of the base layer which the depletion layer does not reach is defined as a first base layer B1 and a region of the base layer which the depletion layer reaches is defined as a second base layer B2. According to the present embodiment, as shown in FIG. 2, silicon germanium does not exist in the second base layer B2 and silicon germanium exists only in the first base layer B1. Thereby, the depletion layer does not reach the silicon germanium when the bipolar transistor is in a non-saturated operation state. The thickness of the second base layer B2 is about 10 nm, for example. This thickness is determined considering the depletion layer extending toward the side of the base when an inverse bias of about 1 volt is applied between the collector and the base. Incidentally, since the extension of the depletion layer also depends on the impurity concentrations of the base layer and the collector layer, the thickness of the second base layer B2 is determined considering the impurity concentrations thereof.

In general, the energy gap of silicon is about 1.1 eV while the energy gap of germanium is low at about 0.67 eV, and the breakdown field of silicon is about 30V/μm while the breakdown field of germanium is low at about 8 V/μm.

According to the present embodiment, however, since germanium is not contained in the region indicated by D2 where the depletion layer expands, a collector-base breakdown voltage (BVcbo) can be prevented from becoming lower. Further, an emitter-collector breakdown voltage (BVceo) correlated with the collector-base breakdown voltage can be prevented from becoming lower. As a result, an operation voltage range of the bipolar transistor is not narrowed.

That is, since the bipolar transistor provided in the present embodiment has a heterojunction, a high cut-off frequency f_{T} can be obtained, and since germanium is not contained in the region indicated by D2, the BVcbo and BVceo can be prevented from becoming lower.

Refer to FIG. 1 again. A PMOS transistor is formed in the MIS transistor region. An N-type well 31 is formed on a surface region of the silicon substrate 10, and a P⁺-type source layer 32 and a P⁺-type drain layer 34 are provided in the N-well 31 on both sides of a N-type channel portion 30. Further, a gate portion 38 is formed above the channel portion 30 via a gate insulating film 36. Furthermore, a source electrode S, a drain electrode D and a gate electrode G are electrically connected to the source layer 32, the drain layer 34 and the gate portion 38, respectively. Thus, the PMOS transistor provided with the source electrode S, the drain electrode D and the gate electrode G is provided. Besides the N-type well 31, a P-type well 33 is also formed on the surface region of the silicon substrate 10, and a NMOS transistor (not shown) is provided in the region of the well 33. Thus, a CMOS provided with both of the NMOS transistor and the PMOS transistor is formed in the MIS transistor region.

Next, a method for manufacturing a BICMOS 220 according to the present embodiment will be shown. According to the present embodiment, for example, a P-type silicon substrate 10 having a surface orientation (100) and a specific resistance=10 ohm*cm is used. Incidentally, brackets in the drawings indicate conductive types.

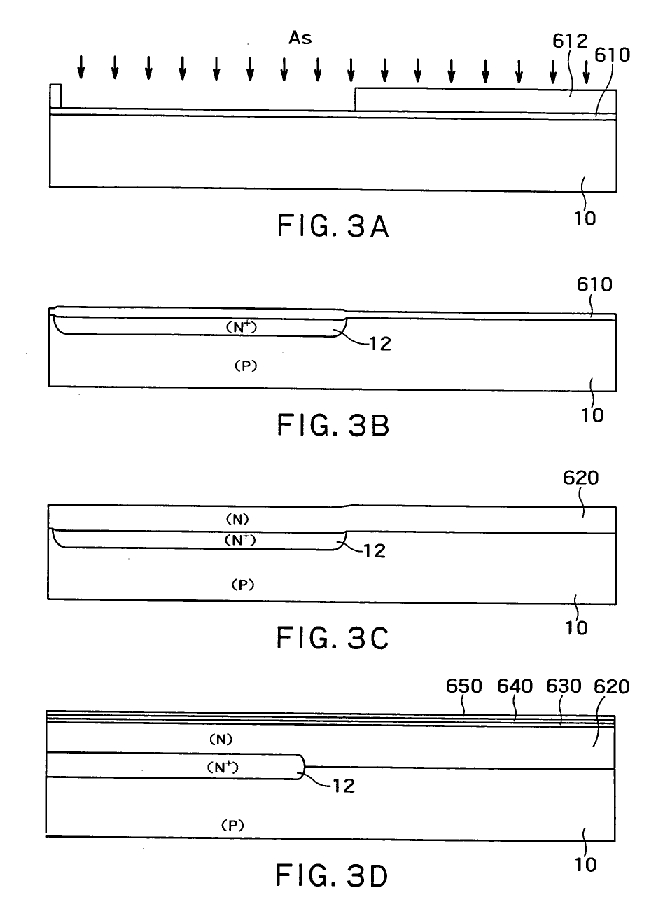

As shown in FIG. 3A, first, a silicon oxide film 610 is formed by oxidizing a silicon substrate 10. A photo resist 612 is provided on the silicon oxide film 610, then the photo resist 612 is patterned. Arsenic (As) of N-type impurity is ion-implanted into a region in which a N⁺-type buried layer 12 serving as a collector of a NPN transistor is formed, using the photo resist 612 as a mask. This ion-implantation is treated, for example, on the condition that an acceleration voltage is about 50 kV and a dose amount is about 8×10¹⁵ cm⁻².

Referring to FIG. 3B, after removal of the photo resist 612, annealing for about 60 minutes is conducted in a nitrogen (N₂) atmosphere at a temperature of about 1000° C. Next, oxidizing processing for about 9 minutes is conducted in an oxygen and hydrogen (O₂+H₂) atmosphere at a temperature of about 1025° C. At this time, the oxide film 610 on the buried layer 12 is oxidized to be thicker than the oxide film 610 of the region where arsenic (As) has not been ion-implanted. The oxide film on the buried layer 12 is about 200 nm, for example. Thereby, a step portion with about 40 nm is formed around the buried layer 12. The step portion is utilized as a reference for alignment in photolithography conducted later. Next, annealing for about 25 minutes is conducted in a nitrogen (N₂) atmosphere at a temperature of about 1190° C. so that arsenic diffuses sufficiently.

As shown in FIG. 3C, next, the oxide film 610 is removed, and an epitaxial layer 620, which is added with only phosphorus (P) of about 1×10¹⁶ cm⁻³, is formed so as to have a thickness of about 0.9 μm. The epitaxial layer 620 is epitaxially grown under the conditions of a pressure of 4000 Pa and a temperature of about 1050° C. using impurity gas PH₃ and silane gas (SiH₄).

As shown in FIG. 3D, a silicon oxide film 630 with a thickness of about 25 nm is next formed by thermal oxidation at a temperature of about 850° C. Further, a polycrystalline silicon 640 with a thickness of about 390 nm and a silicon oxide film 650 with a thickness of about 300 nm are respectively formed by a low-pressure CVD (LP-CVD) process. The buried layer 12 is diffused to a lower portion of the silicon single crystal layer 620 by heat generated when the silicon oxide film 630, the polycrystalline silicon 640 and the silicon oxide film 650 are formed.

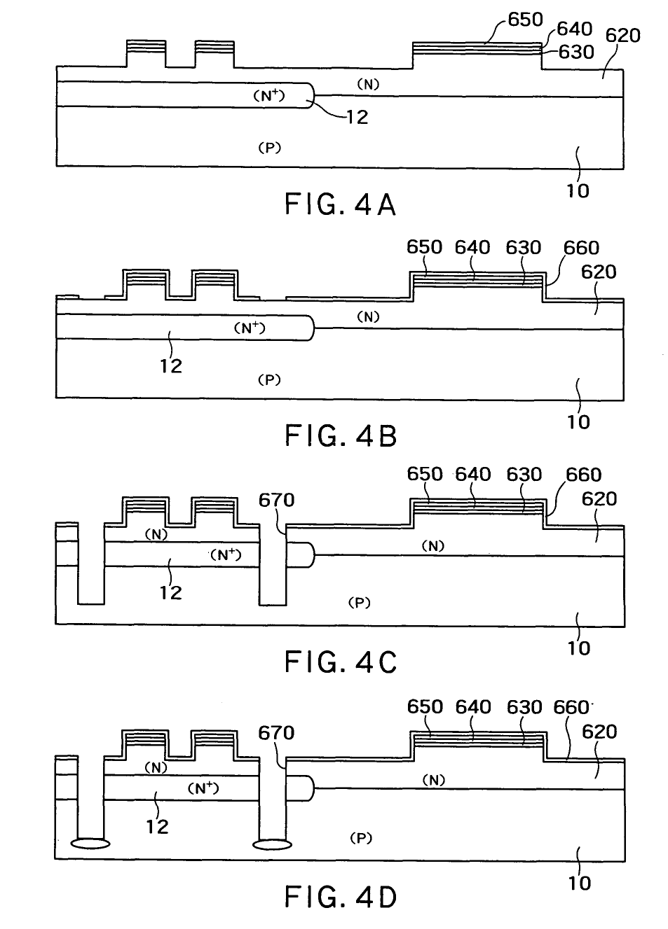

As shown in FIG. 4A, in order to form a shallow STI (Shallow Trench Isolation), the silicon oxide film 630, the polycrystalline silicon 640 or the silicon oxide film 650 is next patterned by a photolithography process and an anisotropic etching such as an RIE process or the like, and the photo resist is removed.

Next, the epitaxial layer 620 is etched to a depth of about 0.5 μm by such an anisotropic etching as an RIE process or the like using the silicon oxide film 650 as a mask.

As shown in FIG. 4B, a silicon oxide film 660 is next deposited by a low-pressure CVD process or the like. Next, in order to form a deep STI, a photo resist with an opening width of about 1.0 μm is patterned so as to surround a device. The silicon oxide film 660 is etched by an anisotropic etching such as an RIE process or the like using the photo resist as a mask, and then the photo resist is further removed.

As shown in FIG. 4C, an anisotropic etching such as an RIE process or the like is next performed using the silicon oxide film 660 as a mask to form a trench 670 with a depth of about 5 μm, for example.

As shown in FIG. 4D, next, boron is ion-implanted to a bottom of the trench 670 on the condition that an acceleration voltage is about 35 KV and a dose amount is 5×10¹³ cm⁻². This is for increasing the breakdown voltage of device isolation of the STI.

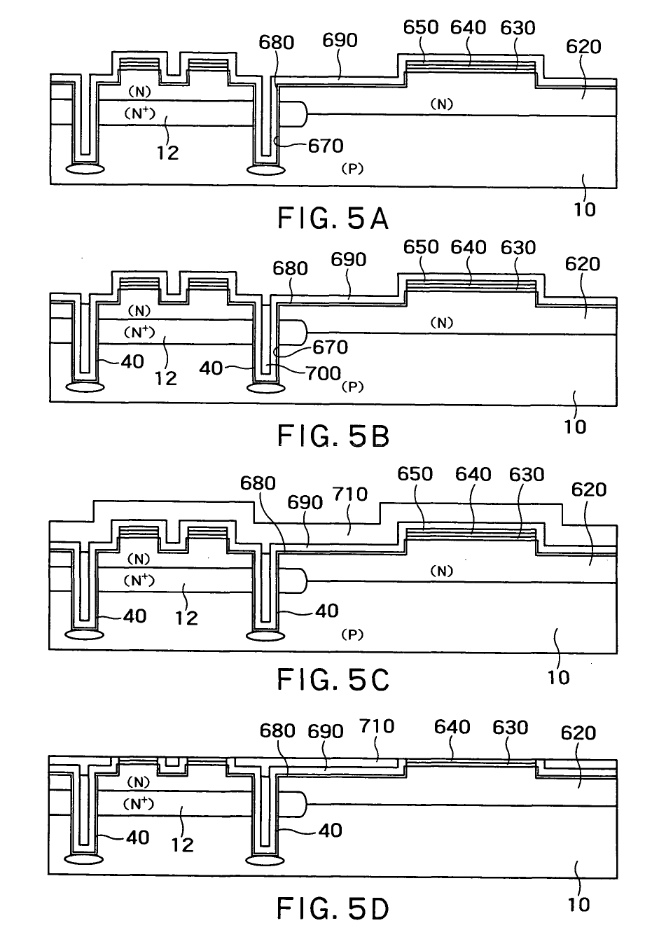

As shown in FIG. 5A, the silicon oxide film 660 is next removed by an etching using ammonium fluoride (NH₄F) or the like. Next, a silicon oxide film 680 with a thickness of about 35 nm is formed on an inner wall of the trench 670 by conducting oxidization at a temperature of about 1000° C. Next, a silicon oxide film 690 with a thickness of about 200 nm is formed on an inner wall of the trench 670 by a low-pressure CVD process or the like.

As shown in FIG. 5B, a polycrystalline silicon with a thickness of about 1.4 μm is next deposited by a low-pressure CVD process or the like, and polycrystalline silicon 700 is filled in only the trench 670 by etching back this polycrystalline silicon by a CDE (Chemical Dry Etching) process or the like. Thus, a device isolation portion 40 is formed.

As shown in FIG. 5C, a silicon oxide film 710 with a thickness of about 650 nm is next formed by a low-pressure CVD process or the like.

As shown in FIG. 5D, next, the silicon oxide film 710 is uniformly polished and etched down to a surface of the polycrystalline silicon 640 using a CMP (Chemical Mechanical Polishing) process.

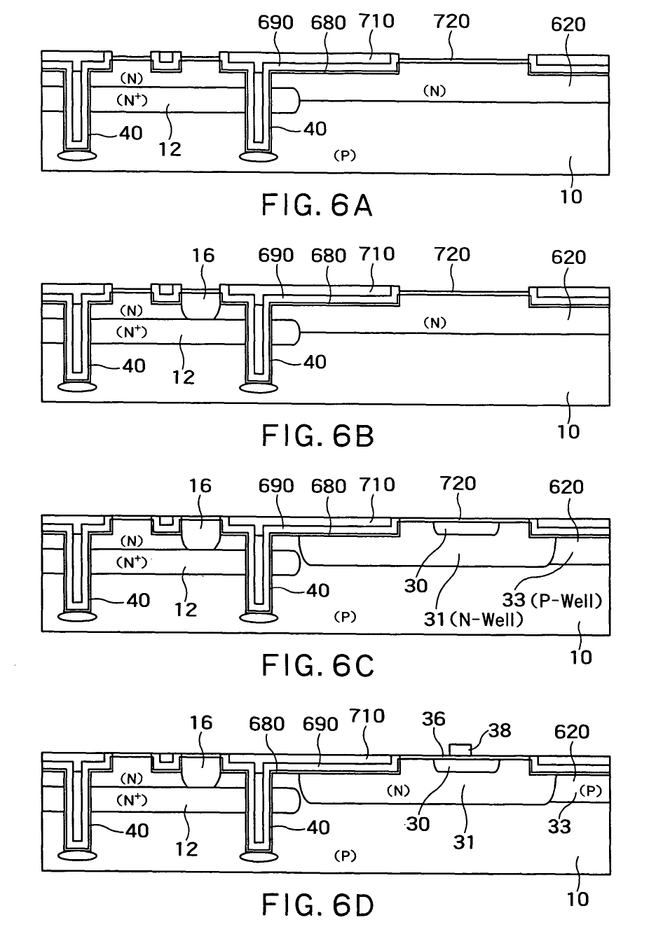

As shown in FIG. 6A, the polycrystalline silicon 640 is next etched by a CDE process or the like, and the silicon oxide film 630 is etched using ammonium fluoride (NH₄F) or the like. Thereafter, a silicon oxide film 720 with a thickness of about 15 nm is formed by conducting oxidation at a temperature of about 850° C.

As shown in FIG. 6B, phosphorus (P) is next ion-implanted into a collector portion of the NPN bipolar transistor. The ion-implantation is conducted on the condition that an acceleration voltage is about 50 kV and a dose amount is about 1.5×10¹⁵ cm⁻². Thereafter, the phosphorus is sufficiently diffused by conducting annealing for about 60 minutes in a nitrogen (N₂) atmosphere at a temperature of about 950° C. so that the lead layer 16 is formed.

As shown in FIG. 6C, next, boron ions (B⁺) are ion-implanted selectively into a P-type well region. The ion implantation is conducted on the condition that an acceleration voltage is about 400 kV and a dose amount is about 2×10¹³ cm⁻² and on the condition that an acceleration voltage is about 160 kV and a dose amount is about 1.1×10¹² cm⁻². A profile (retrograde-type profile) where an ion concentration increases in a direction of depth of the silicon substrate 10 is formed by the ion implantation conducted on these conditions. Thereby, a sheet resistance of the P-type well can be reduced.

Next, phosphorus ions (P⁺⁺) are ion-implanted selectively into the N-type well region. The ion-implantation is conducted on the condition that an acceleration voltage is about 340 kV and a dose amount is about 5.0×10¹³ cm⁻².

Further, annealing for about 0.5 minutes is conducted in a nitrogen (N₂) atmosphere at a temperature of about 1050° C. Thereby, impurities in the P-type well region and the N-type well region are diffused so that a P-type well 33 and an N-type well 31 are formed.

Next, boron ions (B⁺) are selectively implanted into a NMOS channel region (not shown). The ion implantation is conducted on the condition that an acceleration voltage is about 120 kV and a dose amount is about 8×10¹² cm⁻² and on the condition that an acceleration voltage is about 25 kV and a dose amount is about 2.8×10¹² cm⁻².

Next, phosphorus ions (P⁺⁺) are selectively implanted into the PMOS channel region. The ion implantation is conducted on the condition that an acceleration voltage is about 150 kV and a dose amount is about 1.6×10¹³ cm⁻², and on the condition that an acceleration voltage is about 150 kV and a dose amount is about 1.8×10¹³ cm⁻². Further, boron ions (B⁺) are implanted into the PMOS channel region on the condition that an acceleration voltage is about 20 kV and a dose amount is about 4.8×10¹² cm⁻². Thereby, a channel portion 30 is formed.

Referring to FIG. 6D, after the silicon oxide film 720 is next etched using ammonium fluoride (NH₄F) or the like, a gate insulating film 36 comprising a silicon oxide film with a thickness of about 9 nm is formed by conducting oxidization at a temperature of about 850° C. Next, polycrystalline silicon is deposited so as to have a thickness of about 300 nm by a low-pressure CVD process or the like, and arsenic is ion-implanted into the polycrystalline silicon. The ion implantation is conducted, for example, on the condition that an acceleration voltage is about 40 kV and a dose amount is about 1×10¹⁵ cm⁻². Next, the polycrystalline silicon is etched by using a photolithography technique and an etching such as an RIE process or the like so that a gate portion 38 is formed.

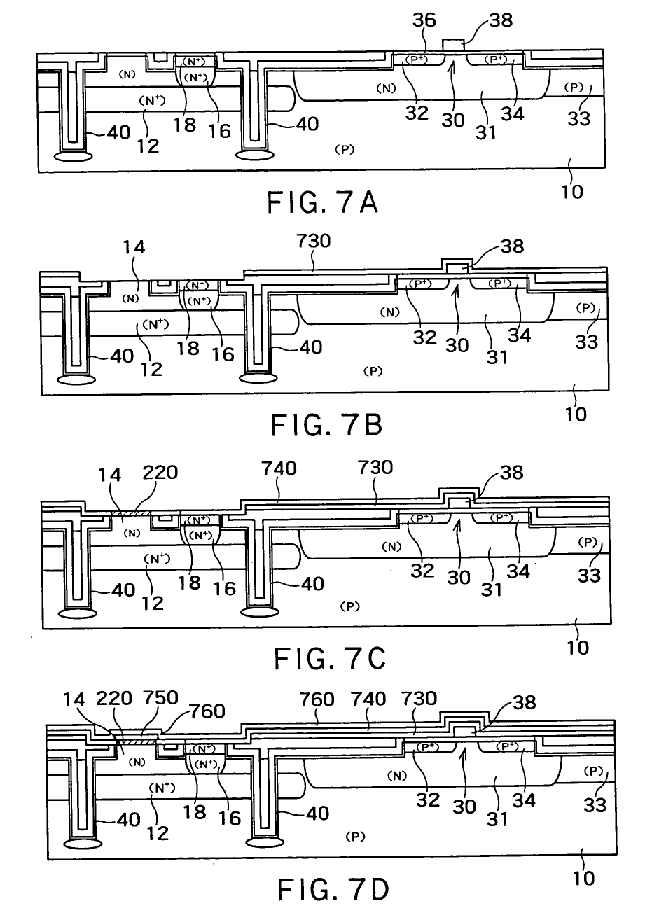

As shown in FIG. 7A, next, arsenic ions (As⁺) are selectively implanted into source and drain portions (not shown) of the NMOS transistor, a N-type well lead portion (not shown) and the lead layer 16 of the NPN bipolar transistor. The ion implantation is conducted, for example, on the condition that an acceleration voltage is about 50 kV and a dose amount is about 5×10¹⁵ cm⁻².

Next, boron ions (B⁺) are selectively implanted into the source and drain portions 32 and 34 of the PMOS transistor and a P-well lead portion (not shown). The ion implantation is conducted on the condition that an acceleration voltage is about 35 kV and a dose amount is about 3.0×10¹⁵ cm⁻². In this step, the source layer 32 and the drain layer 34 of the PMOS transistor are formed, and the contact layer 18 of the NPN bipolar transistor is formed.

As shown in FIG. 7B, next, a silicon oxide film 730 with a thickness of about 200 nm is deposited by a CVD process. Thereafter, a silicon oxide film in a device region of the NPN bipolar transistor is removed by conducting a photolithography process and etching process using ammonium fluoride. Therefore, the epitaxial layer 620 (hereinafter, referred to as a silicon single crystal layer 14) is exposed.

As shown in FIG. 7C, a Si—SiGe—Si stacked film 220 is next formed by epitaxially growing silicon (Si), silicon germanium (SiGe) and silicon (Si) continuously. The epitaxial growth is conducted on the condition that a silicon single crystal is selectively grown on the silicon single crystal layer 14 and simultaneously polycrystalline silicon is grown on a region where the silicon single crystal layer 14 has not been exposed.

In detail, film forming is conducted under the following conditions.

First, in order to prevent film roughness of a portion where the silicon single crystal layer 14 has not been exposed, a non-doped silicon film with a thickness of about 40 nm is formed. At this time, for example, a pressure applied is set to a range of at least 0.13 Pa and at most 1.3×10⁴ Pa and a temperature is set to about 600° C. Further, hydrogen (H₂) is used as carrier gas, and silane (SiH₄) is used as source gas.

Next, a non-doped silicon germanium (Si_{(1-X)}Ge_{(X)}) with a thickness of about 20 nm is formed, where X=0.2, for example. Further, at this time, for example, a pressure applied to a range of at least 0.13 Pa and at most 1.3×10⁴ Pa, and a temperature is set to about 600° C. Further, hydrogen (H₂) is used as carrier gas, and silane (SiH₄) and germanium hydride (GeH₄) are used as source gases.

Next, a doped silicon germanium (Si_{(1-X)}Ge_{(X)}) with a thickness of about 30 nm, which is added with boron as P-type impurity, is formed. At this time, for example, a pressure applied to a range of at least 0.13 Pa and at most 1.3×10⁴ Pa and a temperature is set to about 600° C. Hydrogen (H₂) is used as carrier gas, and silane (SiH₄) and germanium hydride (GeH₄) are used as source gases. X in the silicon germanium (Si_{(1-X)}Ge_{(X)}) can be gradually changed from 0.2 to 0 from the side of the collector toward the side of the emitter by changing a flow rate of the germanium hydride (GeH₄). Thereby, a percentage content of germanium can gradually be reduced in depth from 60 nm to 30 nm, as shown in FIG. 2.

When the doped silicon germanium film is formed, boron hydride (B₂H₆) gas is added such that the boron concentration is constant in the silicon germanium film and is about 8×10¹⁸ cm⁻³.

Next, a silicon film with a thickness of about 30 nm is formed. At this time, for example, a pressure applied to a range of at least 0.13 Pa and at most 1.3×10⁴ Pa, and a temperature is set to about 600° C. Hydrogen (H₂) is used as carrier gas, and silane (SiH₄) is used as source gas. When the silicon film is grown, boron hydride (B₂H₆) gas is added such that a boron concentration is constant in the silicon film and is about 8×10¹⁸ cm⁻³.

The Si—SiGe—Si stacked film 220 is formed via such steps. Incidentally, a stacked film 220 of single crystal silicon (Si)-silicon germanium (SiGe)-silicon (Si) is formed on the silicon single crystal layer 14. On the other hand, a stacked film 740 of polycrystalline silicon (Si)-silicon germanium (SiGe)-silicon (Si) is formed on the silicon oxide film and the polycrystalline silicon other than the silicon single crystal layer 14.

As shown in FIG. 7D, a silicon oxide film is next deposited by a CVD process or the like, and it is patterned so that a silicon oxide film 750 is formed on the Si—SiGe—Si stacked film 220. Next, a polycrystalline silicon 760 with a thickness of about 200 nm is deposited by a CVD process or the like.

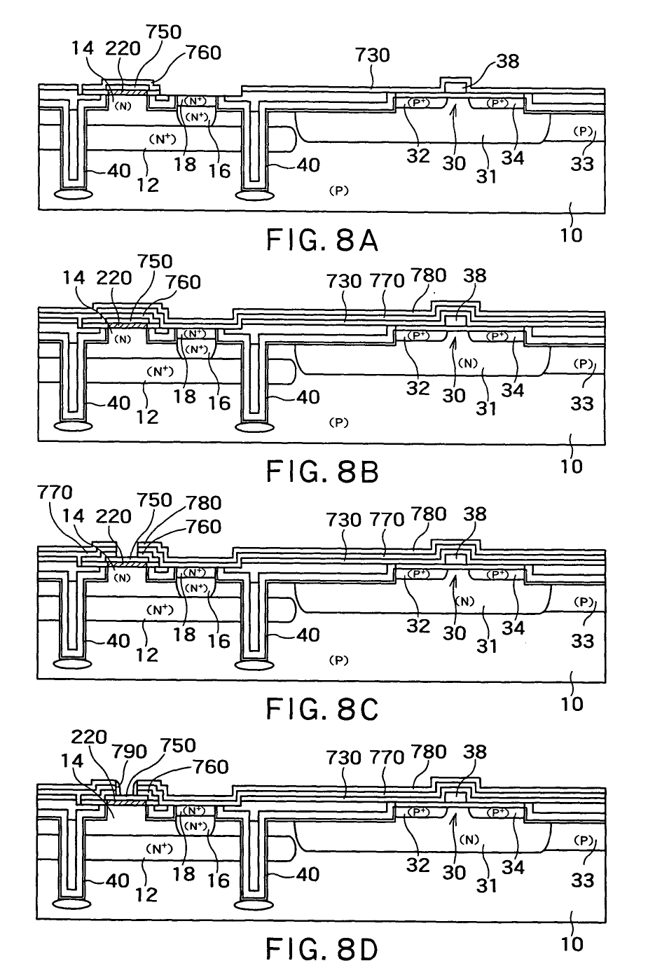

As shown in FIG. 8A, the polycrystalline silicon 760 and the polycrystalline Si—SiGe—Si stacked film 740 are next etched using a photolithography technique and an etching process such as an RIE process or the like.

As shown in FIG. 8B, a silicon oxide film 770 and a silicon nitride film 780 are each deposited so as to have a thickness of about 100 nm by a CVD process.

As shown in FIG. 8C, the silicon nitride film 780, the silicon oxide film 770 and the polycrystalline silicon 760 on the Si—SiGe—Si stacked film 220 are continuously etched using a photolithography technique and an etching process such as an RIE process or the like. Next, phosphorus for a collector is ion-implanted into the non-doped silicon film, which film is deposited on the silicon single crystal layer 14 of the Si—SiGe—Si stacked layer 220. The ion implantation is conducted, for example, on the condition that an acceleration voltage is about 200 kV and a dose amount is about 5×10¹¹ cm⁻².

As shown in FIG. 8D, a silicon nitride film with a thickness of about 100 nm is next deposited by a low-pressure CVD process and side walls 790 comprising a silicon oxide film are formed by etching isotropically the film using an RIE process.

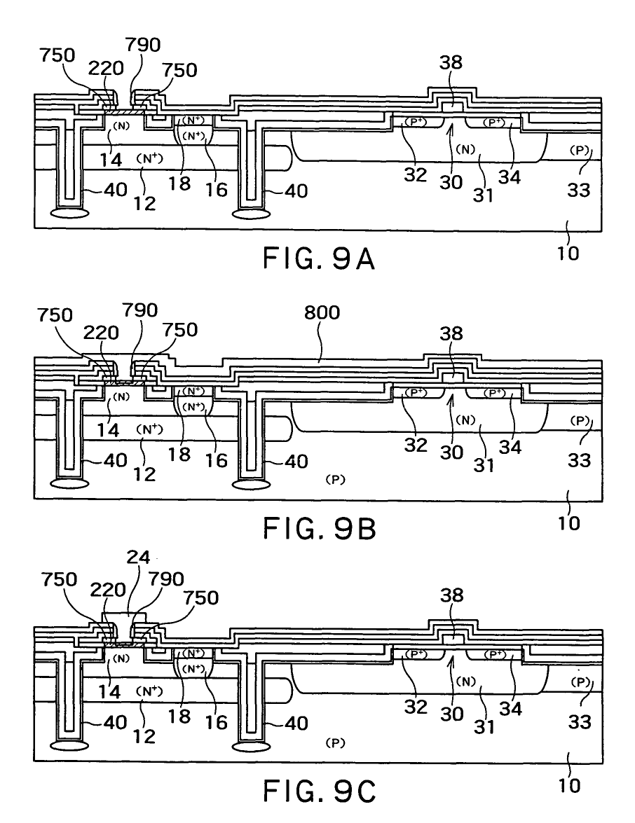

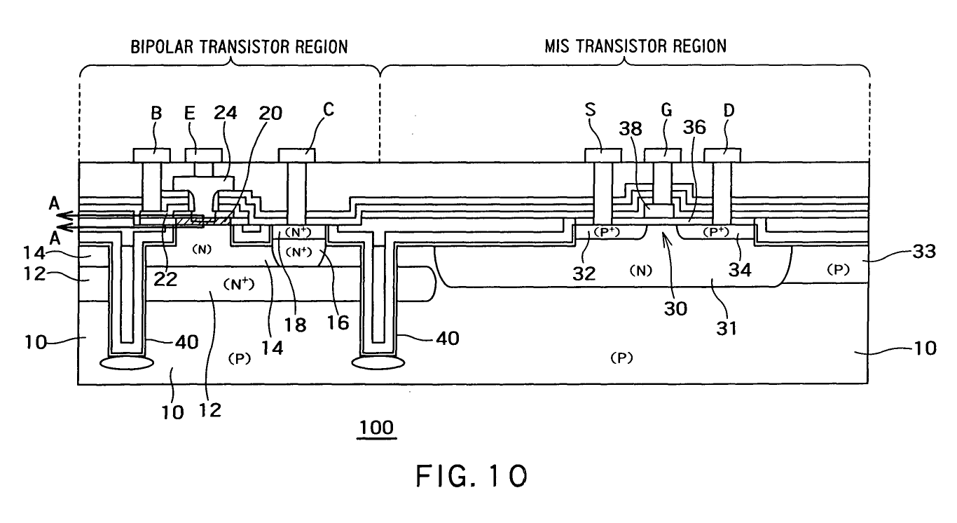

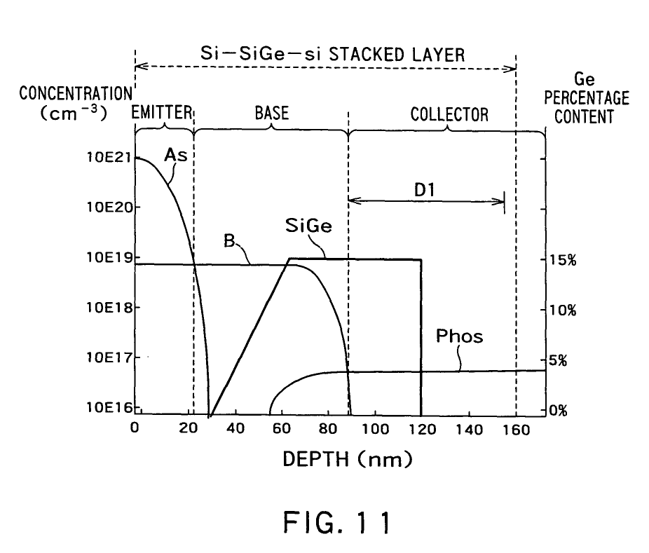

As shown in FIG. 9A, the silicon oxide film 750 is next etched by etching process using ammonium fluoride (NH₄F) or the like.

As shown in FIG. 9B, a polycrystalline 800 with a thickness of about 200 nm is next deposited by a CVD process or the like. Arsenic is ion-implanted into the polycrystalline silicon 800. The ion implantation is conducted on the condition that an acceleration voltage is about 50 kV and a dose amount is about 1×10¹⁶ cm⁻².

As shown in FIG. 9C, next, a polycrystalline silicon 24 connected to the emitter layer is formed by using a photolithography technique and an RIE process. Next, annealing is conducted for about 10 minutes in a nitrogen (N₂) atmosphere at a temperature of about 900° C., for example. Thereby, impurities in the polycrystalline silicon 24 are diffused to an upper portion of the Si—SiGe—Si stacked film 220 and the impurities in the polycrystalline silicon 24 and the Si—SiGe—Si stacked film 220 are activated.

A silicon oxide film 810 is next deposited by a CVD process. The silicon oxide film 810 is planarized by a CMP process. Thereafter, contact holes are formed and electrode are formed with aluminum wirings. Thus, by a series of processes, the manufacturing of the BICMOS 200 having both the bipolar transistor and the MOS transistor is completed (FIG. 1).

Incidentally, the conditions of the above-described manufacturing process have been described for one embodiment, and therefore each of the pressure, the temperature, the acceleration voltage and the like is not limited to the above-described values. Further, the film thickness of each constitution element formed in each step or the like is not limited to the above-described values.

The above-described semiconductor device has a heterojunction between the base and the emitter for making a cut-off frequency f_{T} high, and is able to make an emitter-collector breakdown voltage higher than that of a conventional bipolar transistor

According to the above-described method for manufacturing the semiconductor device, a semiconductor device can be manufactured with an emitter-collector breakdown voltage higher than that of a conventional bipolar transistor, while having a heterojunction between the base and the emitter for making a cut-off frequency f_{T} high.

What is claimed is:

1. A semiconductor device comprising:
a collector layer comprising a first kind of semiconductor material;
a base layer including a first base portion and a second base portion, said first base portion coming in contact with the first collector layer and comprising the first kind of semiconductor material, said second base portion coming in contact with the first base portion and comprising a second kind of semiconductor material; and
an emitter layer coming in contact with the base layer and comprising the first kind of semiconductor material, said emitter layer forming a heterojunction with the base layer.

2. A semiconductor device according to claim 1, wherein the semiconductor device comprises a bipolar transistor provided with the base layer, the emitter layer and the collector layer, and a MIS transistor formed on the same chip as the bipolar transistor.

3. A semiconductor device according to claim 1, wherein an energy gap of the first kind of semiconductor material is larger than that of the second kind of semiconductor material.

4. A semiconductor device according to claim 1, wherein a breakdown field of the first kind of semiconductor material is larger than that of the second kind of semiconductor material.

5. A semiconductor device according to claim 1, wherein the first kind of semiconductor material is silicon, and the second kind of semiconductor material is silicon germanium.

6. A semiconductor device according to claim 1, wherein a film thickness of the first base portion is set such that, when a bipolar transistor having the base layer, the emitter layer and the collector layer is in a non-saturated operation state, a depletion layer extending from a junction between the collector layer and the base layer does not reach the second base layer.

7. A method for manufacturing a semiconductor device, comprising:
forming a first layer on a semiconductor substrate, said first layer comprising a first kind of semiconductor material which includes impurities for a collector;
forming a second layer, a third layer and a fourth layer on the first layer, said second layer comprising the first kind of semiconductor material which is not doped with impurities, said third layer comprising a second kind of semiconductor material which is not doped with impurities, and said fourth layer comprising the second kind of semiconductor material which includes impurities for a base;
forming a fifth layer on the fourth layer, said fifth layer comprising the first kind of semiconductor material which includes impurities for an emitter; and
diffusing the impurities for a base to the second layer.

8. A method for manufacturing a semiconductor device according to claim 7, wherein during the diffusion of the impurities, the impurities for a base are diffused to the second layer and simultaneously therewith the impurities for an emitter are diffused.

9. A method for manufacturing a semiconductor device according to claim 7, wherein a film thickness of the third layer is determined such that the impurities for a base are diffused to the second layer during the diffusion of the impurities.

10. A method for manufacturing a semiconductor device according to claim 9, wherein a film thickness of the third layer is determined such that the impurities for a base are diffused to the second layer during the diffusion of the impurities.

11. A semiconductor device according to claim 7, wherein an energy gap of the first kind of semiconductor material is larger than that of the second kind of semiconductor material.

12. A semiconductor device according to claim 8, wherein an energy gap of the first kind of semiconductor material is larger than that of the second kind of semiconductor material.

13. A semiconductor device according to claim 9, wherein an energy gap of the first kind of semiconductor material is larger than that of the second kind of semiconductor material.

14. A semiconductor device according to claim 7, wherein a breakdown field of the first kind of semiconductor material is larger than that of the second kind of semiconductor material.

15. A semiconductor device according to claim 8, wherein a breakdown field of the first kind of semiconductor material is larger than that of the second kind of semiconductor material.

16. A semiconductor device according to claim 9, wherein a breakdown field of the first kind of semiconductor material is larger than that of the second kind of semiconductor material.

17. A method for manufacturing a semiconductor device according to claim 7, wherein the first kind of semiconductor material is silicon, and the second kind of semiconductor material is silicon germanium.

18. A method for manufacturing a semiconductor device according to claim 8, wherein the first kind of semiconductor material is silicon, and the second kind of semiconductor material is silicon germanium.

19. A method for manufacturing a semiconductor device according to claim 9, wherein the first kind of semiconductor material is silicon, and the second kind of semiconductor material is silicon germanium.
